(19) United States
(12) Patent Application Publication
(10) Pub. No.: US 2021/0314468 A1
(43) Pub. Date: Oct. 7, 2021

(54) Small Camera with Molding Compound

(71) Applicant: Facebook Technologies, LLC, Menlo Park, CA (US)

(72) Inventor: Minhua Liang, Mukilteo, WA (US)

(21) Appl. No.: 16/941,090

(22) Filed: Jul. 28, 2020

Related U.S. Application Data
(60) Provisional application No. 63/005,185, filed on Apr. 3, 2020.

(51) Int. Cl. H04N 5/225; G02B 3/00

(52) U.S. Cl. CPC H04N 5/2254; H04N 5/2257; G02B 3/0031

(57) ABSTRACT

An imaging module or a camera module includes a lens assembly and an image sensor. Molding compound such as epoxy molding compound (EMC) is disposed around the image sensor to shield ambient light from becoming incident onto the image sensor.

### CROSS-REFERENCE TO RELATED APPLICATIONS

This application claims priority to U.S. provisional Application No. 63/005,185 filed Apr. 3, 2020, which is hereby incorporated by reference.

### BACKGROUND INFORMATION

Cameras have become ubiquitous in consumer electronics. For example, smart phones, tablets, action-cameras, laptops, and even monitors may incorporate a camera. Typically, the cameras that are incorporated into consumer electronics include a lens assembly that is common in smart phones in order to take advantage of the pricing available due to the volume production of these lens assemblies. As cameras become smaller, they can be positioned in new places and used in new contexts.

### BRIEF DESCRIPTION OF THE DRAWINGS

Non-limiting and non-exhaustive embodiments of the invention are described with reference to the following figures, wherein like reference numerals refer to like parts throughout the various views unless otherwise specified.

FIG. 1A illustrates an existing chip scale package (CSP) including an image sensor.

FIG. 1B illustrates a camera module including a uni-body lens assembly disposed over a CSP to focus image light to an image sensor.

FIGS. 2A and 2B illustrate a camera module having molding compound shielding ambient light from an image sensor, in accordance with aspects of the disclosure.

FIG. 3 illustrates an imaging module that includes a camera module, in accordance with aspects of the disclosure.

FIGS. 4A-4B illustrate imaging modules that includes a plurality of camera modules, in accordance with aspects of the disclosure.

FIG. 5 illustrates a Chip On Board (COB) image sensor including an image sensor die adhered to a PCB layer.

FIGS. 6A-6B illustrate a camera module having molding compound shielding ambient light from an image sensor die.

FIG. 7 illustrates an imaging module that includes a camera module having a COB image sensor.

FIGS. 8A-8B illustrate imaging modules that includes a plurality of camera modules, in accordance with aspects of the disclosure.

FIG. 9 illustrates a camera module having molding compound surrounding coverglass disposed over an image sensor die.

FIG. 10 illustrates an imaging module that includes a camera module having a coverglass layer surrounded by molding compound.

FIG. 11A-11B illustrate imaging modules that includes a plurality of camera modules, in accordance with aspects of the disclosure.

FIGS. 12A-12E illustrate imaging module array geometrical formats that includes a plurality of camera modules, in accordance with aspects of the disclosure.

### DETAILED DESCRIPTION

Embodiments of a camera having a molding compound shielding light from the image sensor are described herein. In the following description, numerous specific details are set forth to provide a thorough understanding of the embodiments. One skilled in the relevant art will recognize, however, that the techniques described herein can be practiced without one or more of the specific details, or with other methods, components, materials, etc. In other instances, well-known structures, materials, or operations are not shown or described in detail to avoid obscuring certain aspects.

Reference throughout this specification to “one embodiment” or “an embodiment” means that a particular feature, structure, or characteristic described in connection with the embodiment is included in at least one embodiment of the present invention. Thus, the appearances of the phrases “in one embodiment” or “in an embodiment” in various places throughout this specification are not necessarily all referring to the same embodiment. Furthermore, the particular features, structures, or characteristics may be combined in any suitable manner in one or more embodiments.

In aspects of this disclosure, visible light may be defined as having a wavelength range of approximately 380 nm-700 nm. Non-visible light may be defined as light having wavelengths that are outside the visible light range, such as ultraviolet light and infrared light. Infrared light having a wavelength range of approximately 700 nm-1 mm includes near-infrared light. In aspects of this disclosure, near-infrared light may be defined as having a wavelength range of approximately 700 nm-1.4 μm.

In aspects of this disclosure, the term “transparent” may be defined as having greater than 90% transmission of light. In some aspects, the term “transparent” may be defined as a material having greater than 90% transmission of visible light.

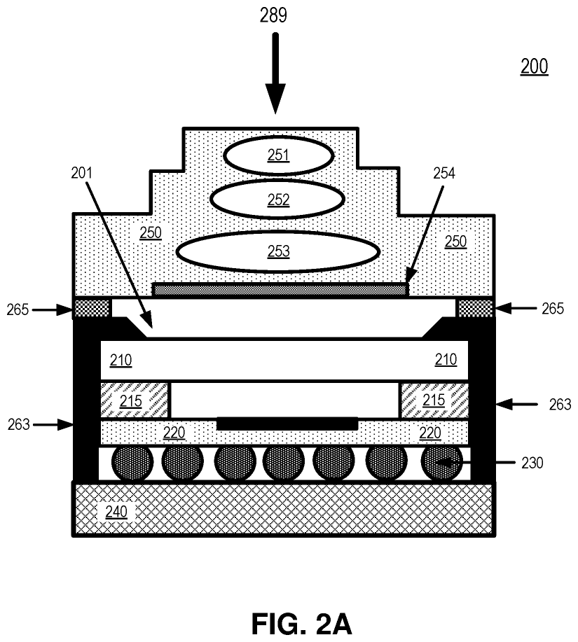

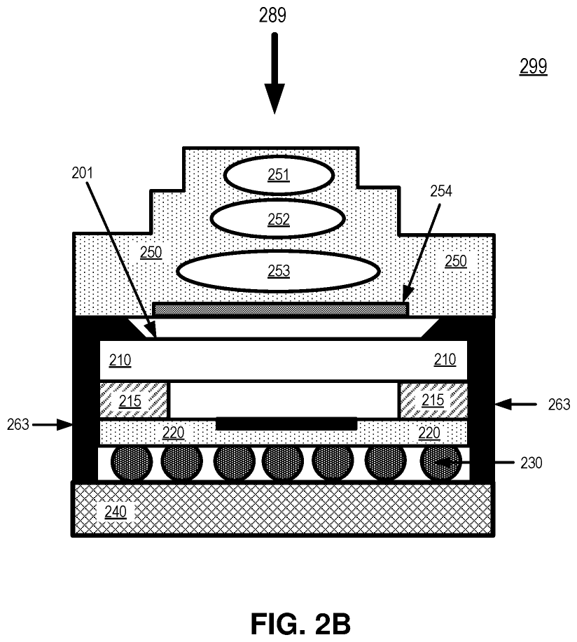

Embodiments of camera modules and imaging module are disclosed that include molding compound disposed to shield an image sensor in Chip Scale Package (CSP) from ambient light. The molding compound may be an epoxy molding compound (EMC), plastic molding compound made of plastic polymer, or other molding compound. By utilizing a molding compound to shield the image sensor in CSP, the footprint of a camera may be reduced compared with existing cameras that use a uni-body lens assembly having a larger footprint. Embodiments of the disclosure may include an EMC shielding an image sensor included in a chip scale package (CSP). A reduced x-y footprint of a camera module that includes the aspects of this disclosure may allow the camera module to be positioned in smaller confines of a device. In some aspects of the disclosure, the reduced x-y footprint of the camera module allows two cameras to be placed very close to each other such that the cameras have almost the same optical perspective. Cameras modules and imaging modules in this disclosure may be included in a head mounted device such as a head mounted display. These and other embodiments are described in more detail in connection with FIGS. 2A-12E.

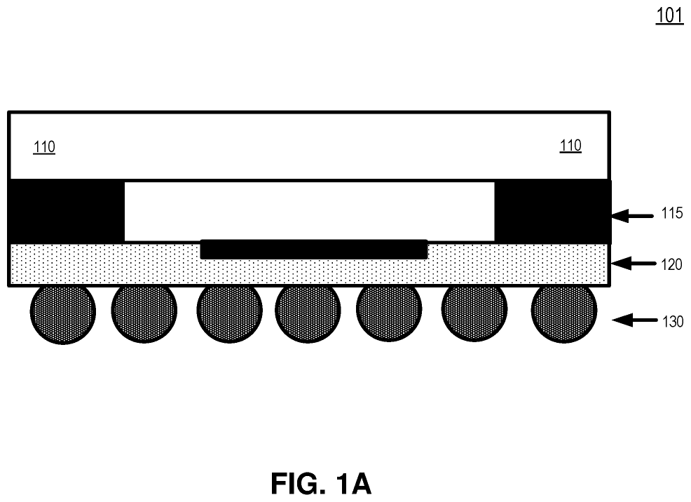

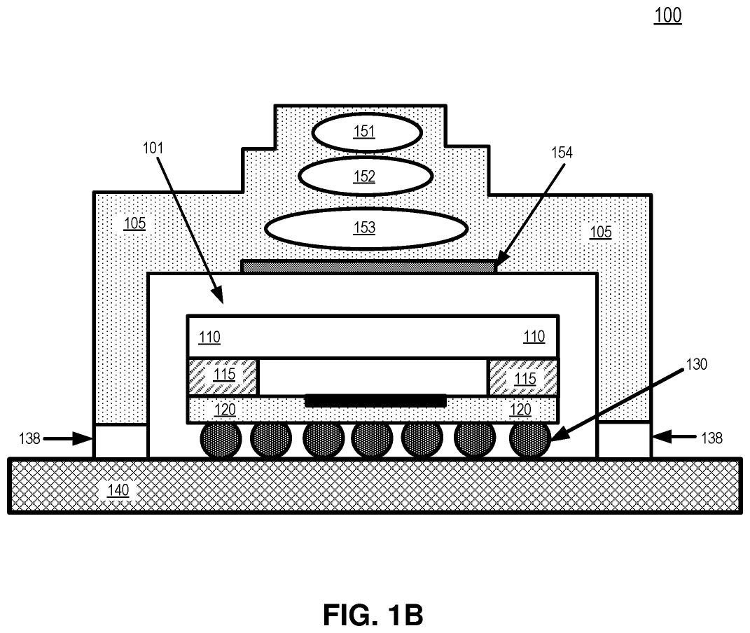

FIG. 1A illustrates an existing chip scale package (CSP) 101 including an image sensor 120. Glue layer 115 adheres coverglass 110 over the image sensor 120 and a solder ball grid array 130 is coupled to electrical inputs/outputs of the image sensor 120.

FIG. 1B illustrates a camera module 100 including a uni-body lens assembly 105 disposed over CSP 101 to focus image light to image sensor 120. Uni-body lens assembly 105 may include a plurality of refractive lenses such as lenses 151, 152, and 153. Uni-body lens assembly 105 may further include one or more filtering layers 154. In FIG. 1B, a frame of uni-body lens assembly 105 may be formed by an injecting molding process, for example. In the illustration of FIG. 1B, glue layer 138 adheres uni-body lens assembly 105 to a printed circuit board (PCB) layer 140 to secure the uni-body lens assembly 105 to focus image light to image sensor 120. Solder ball grid array 130 electrically couples the image sensor 120 to electrical pads (not illustrated) of the PCB layer 140. As shown in FIG. 1B, an air gap between uni-body lens assembly 105 and CSP 101 may be included in camera module 100 to allow for manufacturing tolerances.

FIG. 2A illustrates a camera module 200 that may be significantly narrower than camera module 100 due to molding compound 263 shielding ambient light from image sensor 220, in accordance with aspects of the disclosure. In FIG. 2A, molding compound 263 functions to shield ambient light from reaching image sensor 220 instead of a side of a uni-body lens assembly 105. This reduces a width of camera module 200 compared to camera module 100.

Camera module 200 includes a CSP 201 including a coverglass layer 210 adhered to an image sensor 220 by an adhesive layer 215. A solder ball grid array 230 electrically couples image sensor 220 to electrical pads (not illustrated) of PCB layer 240. Solder ball grid array 230 may be soldered to the electrical pads of PCB layer 240 using a reflow soldering technique, for example. Solder ball grid array 230 may be a two-dimensional solder ball array (e.g. arranged in a 10×10 grid).

After CSP 201 is soldered to PCB layer 240, molding compound 263 may be formed on an outside of CSP 201 to shield ambient light from becoming incident onto image sensor 220. Molding compound 263 also serves as a surface for mounting lens assembly 250. Image sensor 220 may be a complementary metal-oxide semiconductor (CMOS) image sensor. Molding compound 263 is opaque to light. Molding compound 263 may be black. Molding compound 263 may be an epoxy molding compound (EMC) that is molded around CSP 201. In FIG. 2A, a portion of molding compound 263 is disposed between coverglass layer 210 and lens assembly 250. That is, a portion of molding compound 263 is disposed over coverglass layer 210. Molding compound 263 adheres CSP 201 to PCB 240, in FIG. 2A. Molding compound 263 may wrap around CSP 201 and surround the sides of CSP 201.

In FIG. 2A, lens assembly 250 is adhered to molding compound 263 by an adhesive layer 265. FIG. 2B illustrates a camera module 299 where adhesive layer 265 is not included and molding compound 263 adheres lens assembly 250 directly to CSP 201 and PCB layer 240. Molding compound 263 may function as a mounting surface that supports lens assembly 250 in the embodiments of FIG. 2A or 2B. In FIG. 2B, molding compound 263 is a mounting surface that lens assembly 250 is bonded to. In FIG. 2A, molding compound 263 is a mounting surface for lens assembly 250 having an intervening adhesive layer 265.

Referring again to FIG. 2A, lens assembly 250 includes a plurality of lenses 251, 252, and 253 to focus image light 289 to image sensor 220. Lens assembly 250 may also include a filter layer 254. Filter layer 254 may transmit visible light while blocking ultraviolet and infrared light, in some embodiments. Filter layer 254 may transmit infrared light while blocking ultraviolet and visible light, in some embodiments. Filter layer 254 may transmit dual band light, e.g., visible band and near IR band, in some embodiments. Filter layer 254 may transmit more than two spectral bands of light in some embodiments. Filter layer 254 may include a polarization layer configured to transmit a particular polarization orientation while blocking other polarization orientations. Notably, lens assembly 250 is significantly narrower than uni-body lens assembly 105 since lens assembly 250 does not include sidewalls that extend to a PCB layer to shield ambient light from becoming incident on an image sensor. In the illustrated embodiment of FIG. 2A, the molding compound 263 disposed around CSP 201 is substantially a same width as lens assembly 250 so that lens assembly 250 does not add unnecessary width to camera module 200.

Coverglass layer 210 is disposed between lens assembly 250 and image sensor 220, in FIG. 2A. Molding compound 263 surrounds coverglass layer 210 and image sensor 220, in the illustrated embodiment.

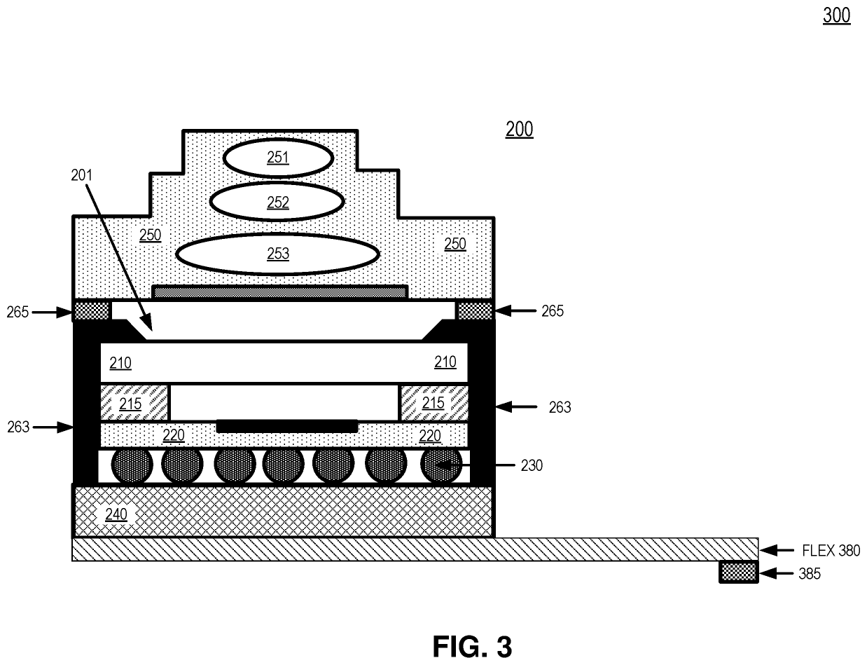

FIG. 3 illustrates an imaging module 300 that includes camera module 200, in accordance with aspects of the disclosure. In FIG. 3, flex circuit layer 380 is electrically coupled to PCB layer 240 of camera module 200 and connector 385 is electrically coupled to flex circuit layer 380. Image sensor 220 may receive electrical power from connector 385 via flex circuit layer 380. Connector 385 may deliver image signals of images captured by image sensor 220 to processing logic for image processing, for example. Connector 385 may deliver an image acquisition initiation signal (via flex circuit layer 380) to image sensor 220 that activates the image sensor 220 to capture one or more images. In some embodiments (not illustrated) a connector is mounted below PCB layer 240 and flex circuit 380 is not included. In this embodiment, through-hole vias in PCB layer 240 may be used to deliver an image acquisition initiation signal to image sensor 220 that actives image sensor 220 to capture one or more images. Power traces to provide electrical power to image sensor 220 may also be provided through the connector and the through-hole vias.

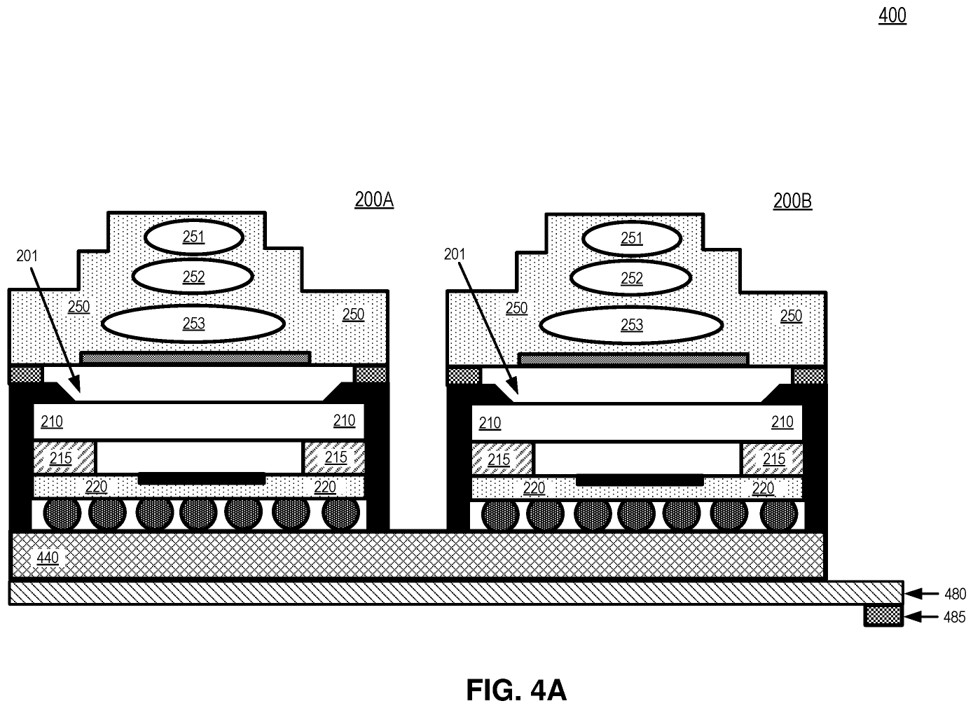

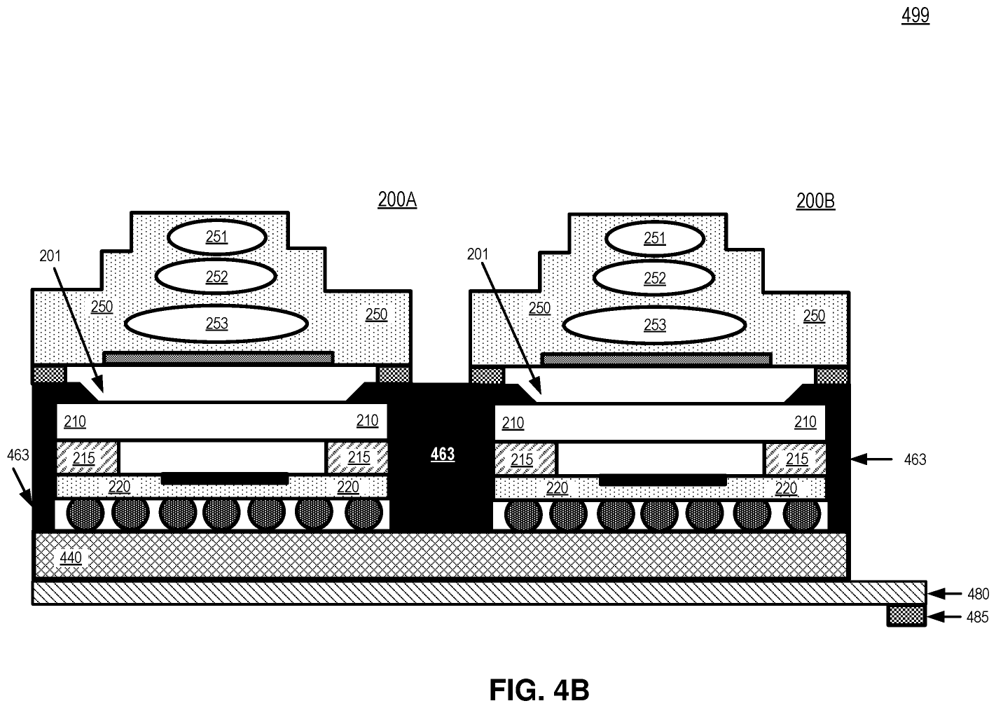

FIG. 4A illustrate an imaging module 400 that includes a plurality of camera modules, in accordance with aspects of the disclosure. In FIG. 4A, camera module 200A and camera module 200B are electrically coupled to PCB layer 440. Camera modules 200A and 200B may be configured as camera module 200. Flex circuit layer 480 is electrically coupled to PCB layer 440 and connector 485 is electrically coupled to flex circuit layer 480. Image sensors 220 of camera modules 200A and 200B may receive electrical power from connector 485 via flex circuit layer 480. Connector 485 may deliver first image signals of first images captured by image sensor 220 of camera module 200A. Connector 485 may also deliver second image signals of second images captured by image sensor 220 of camera module 200B.

Since camera module 200A and camera module 200B have a reduced footprint, they can be placed closer together than existing camera modules. Consequently, image sensors of camera module 200A and camera module 200B may share a more similar optical perspective and be disposed adjacently. This may be advantageous in a variety of contexts. In an embodiment, camera module 200A is configured as red-green-blue (RGB) camera configured to capture visible light images and camera module 200B is configured as a simultaneous localization and mapping (SLAM) camera configured to capture infrared images for mapping purposes. In this context, camera module 200B may include an infrared bandpass filter configured to pass a narrow bandwidth of infrared light that is illuminating an environment to be imaged by camera module 200B. Camera module 200B can also be configured as a depth camera module so that depth pixel information in camera module 200B can be mapped to the corresponding RGB pixel information in camera module 200A.

FIG. 4B illustrates an imaging module 499, in accordance with aspects of the disclosure. Imaging module 499 differs from imaging module 400 in that molding compound 463 is contiguous between camera modules 200A and 200B. In an embodiment, a contiguous layer of molding compound 463 shields ambient light from both image sensors 220 in camera modules 200A and 200B, in FIG. 4B.

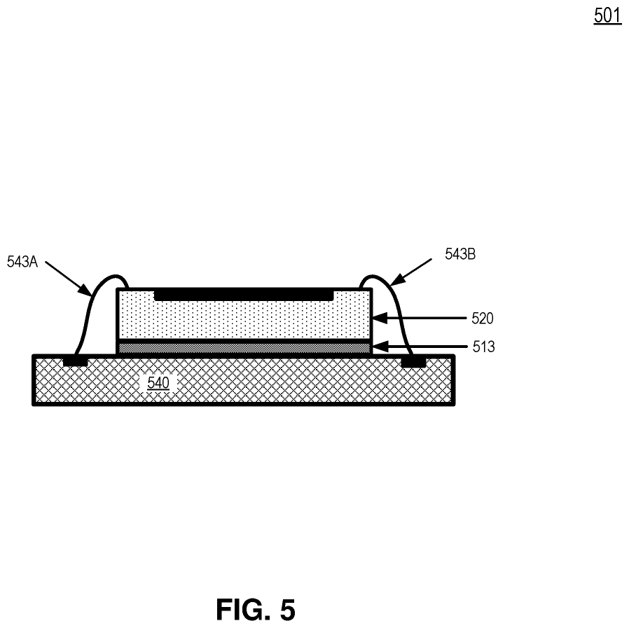

FIG. 5 illustrates a Chip On Board (COB) image sensor 501 including an image sensor die 520 adhered to a PCB layer 540. In FIG. 5, image sensor die 520 is wire-bonded to electrical pads of PCB layer 540 with wire bonds 543A and 543B. Image sensor die 520 may be CMOS image sensor, for example. Adhesive layer 513 also bonds image sensor die 520 to PCB layer 540. Wire bonds 543A and 543B may be gold, for example. More than two wire bonds may be used to provided electrical power to image sensor die 520 and to facilitate delivery of image signals of images captured by image sensor die 520.

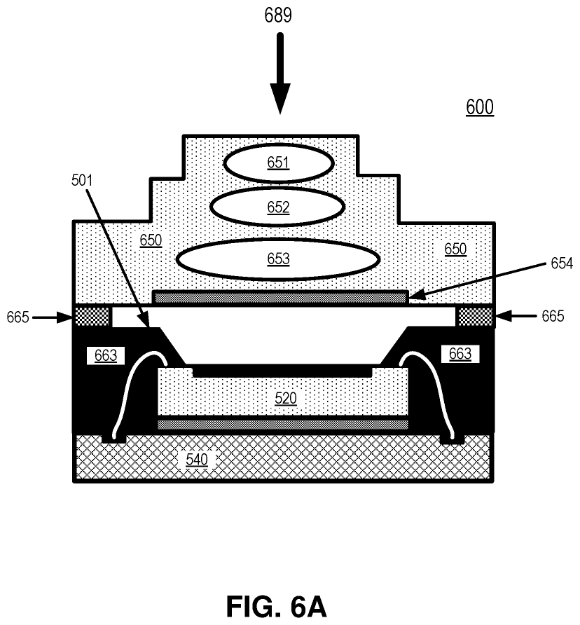

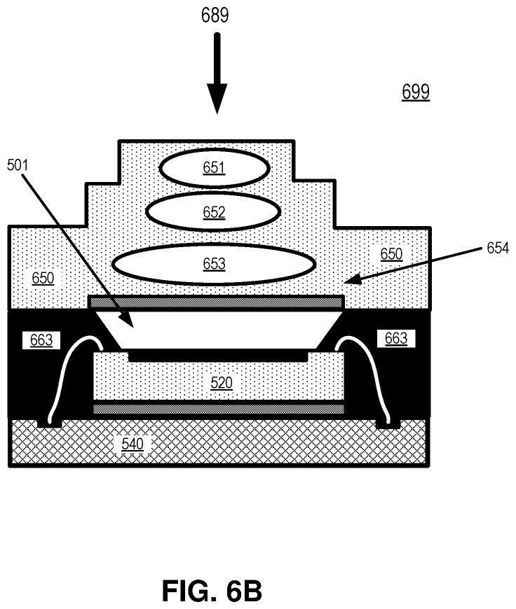

FIG. 6A illustrates a camera module 600 that may be significantly narrower than camera module 100 due to molding compound 663 shielding ambient light from image sensor die 520. In FIG. 6A, molding compound 663 functions to shield ambient light from reaching image sensor die 520 instead of a side of a uni-body lens assembly 105 shielding the ambient light, and serves a mounting surface for lens assembly 650. This reduces a width of camera module 600 compared to camera module 100.

Camera module 600 includes COB image sensor 501. Molding compound 663 may be formed around image sensor die 520 to shield ambient light from becoming incident onto image sensor die 520. Molding compound 663 may encapsulate wire bonds 543 and electrical pads of PCB layer 540. Molding compound 663 is opaque to light. Molding compound 663 may be black. Molding compound 663 may be an EMC that is molded around image sensor die 520. In FIG. 6A, a portion of molding compound 663 is disposed between image sensor die 520 and lens assembly 650. That is, a portion of molding compound 663 is disposed over image sensor die 520. Molding compound 663 adheres image sensor die 520 to PCB 540, in FIG. 6A.

In FIG. 6A, lens assembly 650 is adhered to molding compound 663 by an adhesive layer 665. FIG. 6B illustrates a camera module 699 where adhesive layer 665 is not included and molding compound 663 adheres lens assembly 650 directly to COB image sensor 501 and PCB layer 540.

Lens assembly 650 includes a plurality of lenses 651, 652, and 653 to focus image light 689 to image sensor die 520. Lens assembly 650 may also include a filter layer 654. Filter layer 654 may transmit visible light while blocking ultraviolet and infrared light, in some embodiments. Filter layer 654 may transmit infrared light while blocking ultraviolet and visible light, in some embodiments. Filter layer 654 may transmit dual band light, e.g., visible band and near IR band, in some embodiments. Filter layer 654 may transmit more than two spectral bands of light in some embodiments. Filter layer 654 may include a polarization layer configured to transmit a particular polarization orientation while blocking other polarization orientations. Notably, lens assembly 650 is significantly narrower than uni-body lens assembly 105 since lens assembly 650 does not include sidewalls that extend to a PCB layer to shield ambient light from becoming incident on an image sensor. In the illustrated embodiment of FIG. 6A, the molding compound 663 disposed around image sensor die 520 is substantially a same width as lens assembly 650 so that lens assembly 650 does not add unnecessary width to camera module 200.

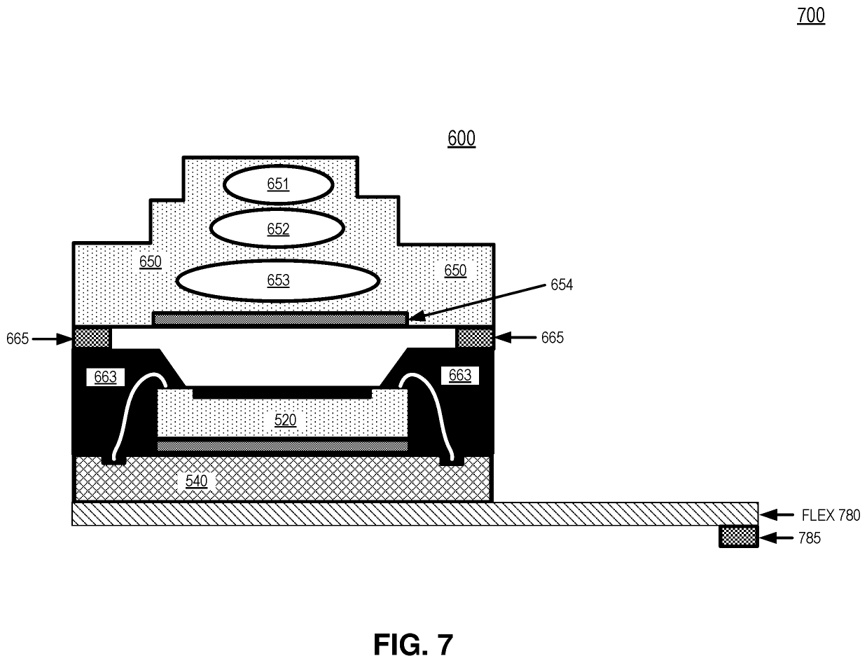

FIG. 7 illustrates an imaging module 700 that includes camera module 600 having a COB image sensor 501. In FIG. 7, flex circuit layer 780 is electrically coupled to PCB layer 540 of camera module 600 and connector 785 is electrically coupled to flex circuit layer 780. Image sensor die 520 may receive electrical power from connector 785 via flex circuit layer 780. Connector 785 may deliver image signals of images captured by image sensor die 520 to processing logic for image processing, for example. Connector 785 may deliver an image acquisition initiation signal (via flex circuit layer 780) to image sensor die 520 that activates the image sensor die 520 to capture one or more images.

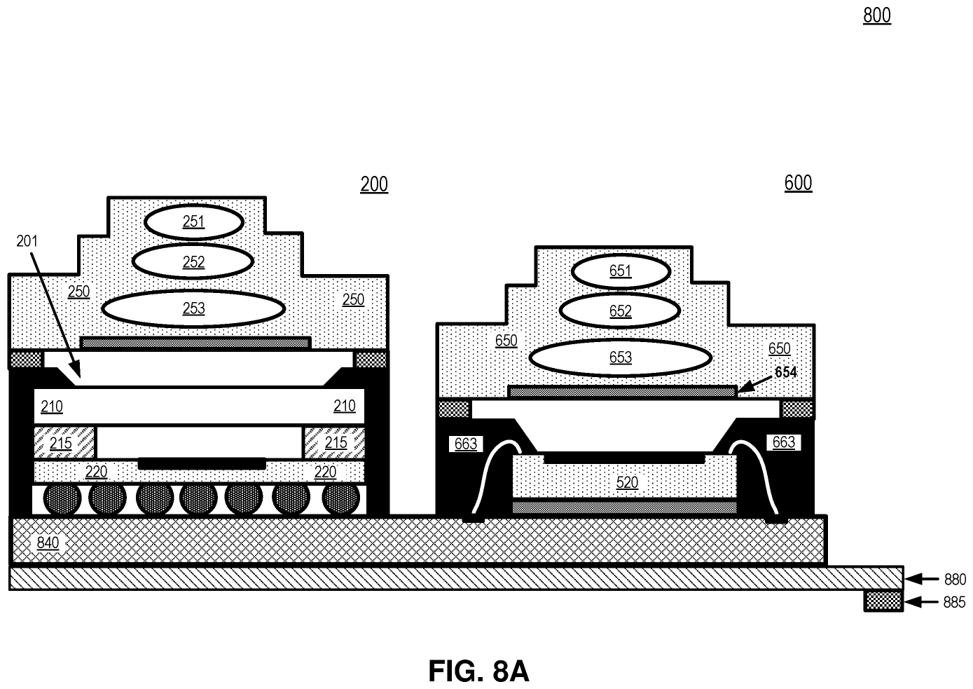

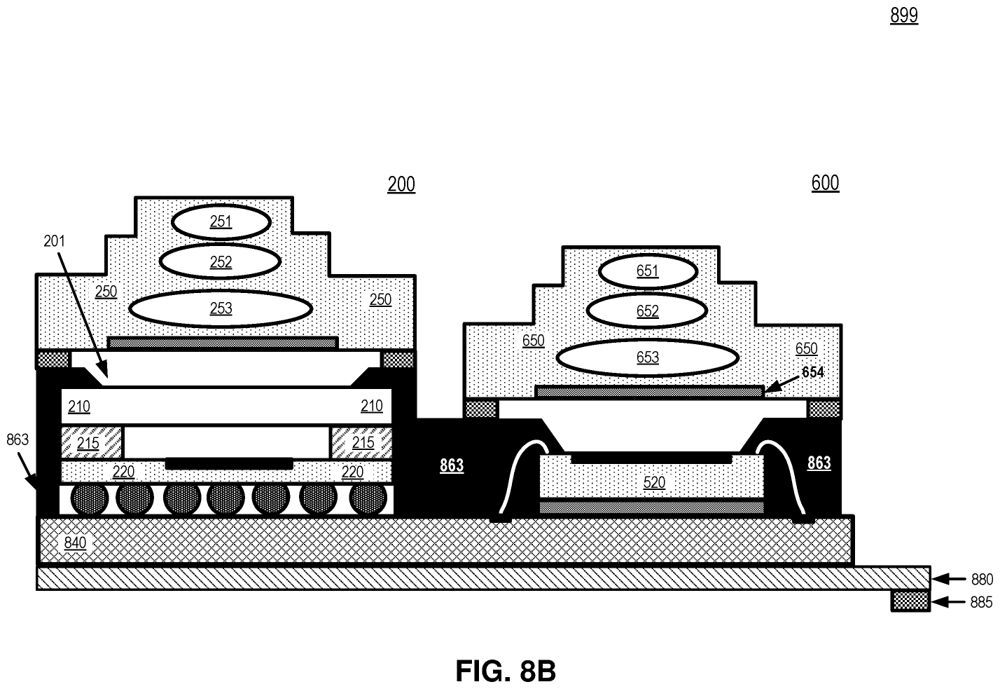

FIG. 8A illustrates an imaging module 800 that includes a plurality of camera modules, in accordance with aspects of the disclosure. In FIG. 8A, camera module 200 and camera module 600 are electrically coupled to PCB layer 840. Flex circuit layer 880 is electrically coupled to PCB layer 840 and connector 885 is electrically coupled to flex circuit layer 880. Image sensor 220 of camera module 200 and image sensor die 520 of camera module 600 may receive electrical power from connector 885 via flex circuit layer 880. Connector 885 may deliver first image signals of first images captured by image sensor 220 of camera module 200. Connector 885 may also deliver second image signals of second images captured by image sensor die 520 of camera module 600.

FIG. 8B illustrates an imaging module 899, in accordance with aspects of the disclosure. Imaging module 899 differs from imaging module 800 in that molding compound 863 is contiguous between camera modules 200 and 600. In an embodiment, a contiguous layer of molding compound 863 shields ambient light from both image sensors 220 and image sensor die 520, in FIG. 8B.

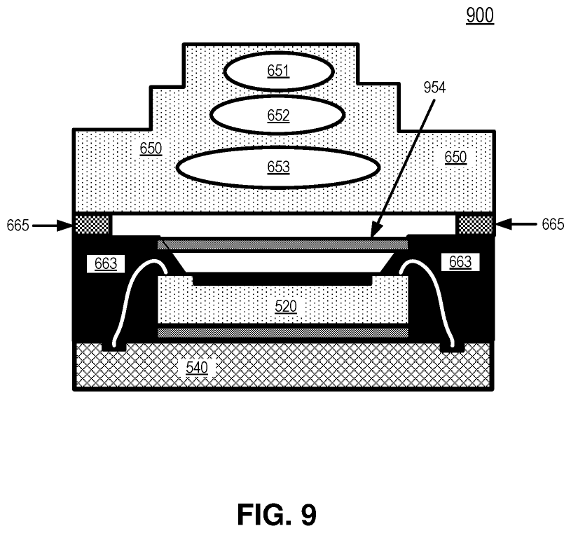

FIG. 9 illustrates a camera module 900. In FIG. 9, coverglass layer 954 is disposed between lens assembly 650 and image sensor die 520 and coverglass layer 954 is surrounded by molding compound 663. Surrounding coverglass layer 954 with molding compound 663 may increase the yield of a Chip On Board configuration by covering image sensor die 520 earlier in the fabrication process of camera module 900.

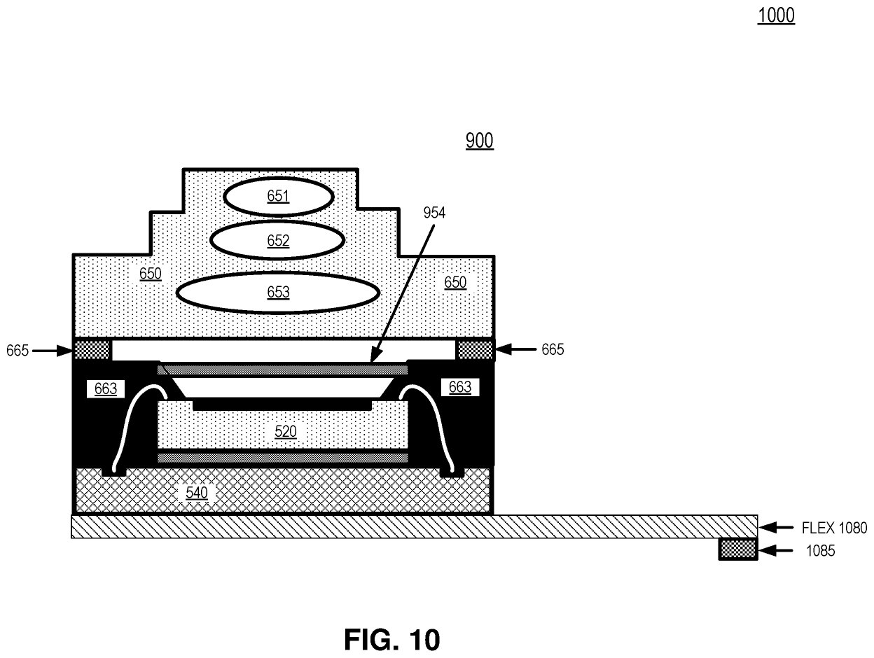

FIG. 10 illustrates an imaging module 1000 that includes camera module 900 having coverglass layer 954 surrounded by molding compound 663. In FIG. 10, flex circuit layer 1080 is electrically coupled to PCB layer 540 of camera module 600 and connector 1085 is electrically coupled to flex circuit layer 1080. Image sensor die 520 may receive electrical power from connector 1085 via flex circuit layer 1080. Connector 1085 may deliver image signals of images captured by image sensor die 520 to processing logic for image processing, for example. Connector 1085 may deliver an image acquisition initiation signal (via flex circuit layer 1080) to image sensor die 520 that activates the image sensor die 520 to capture one or more images.

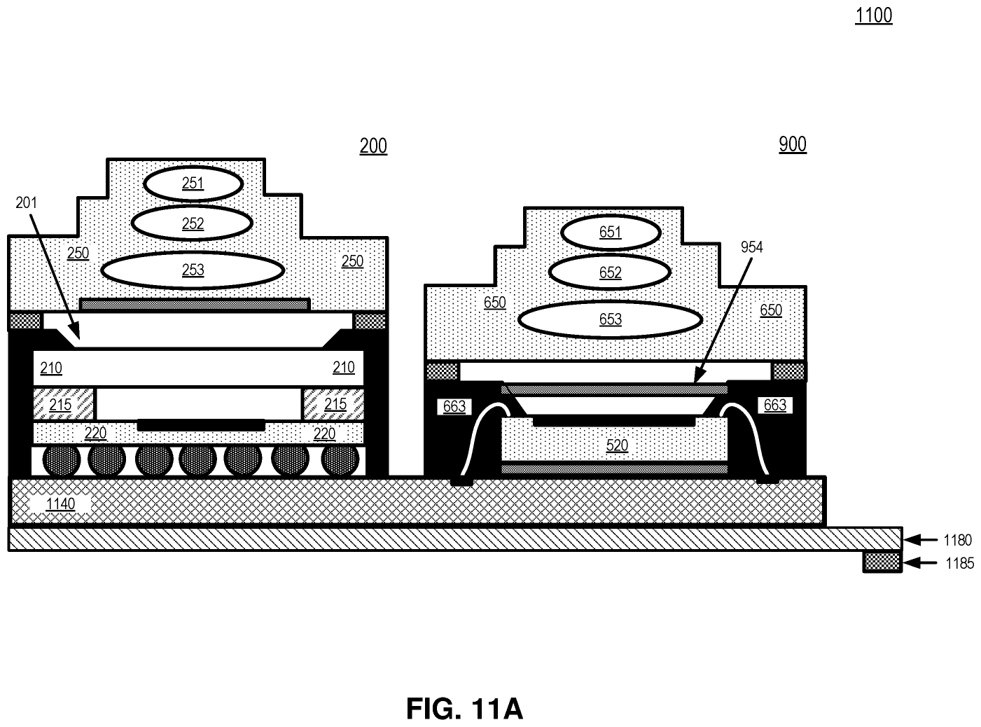

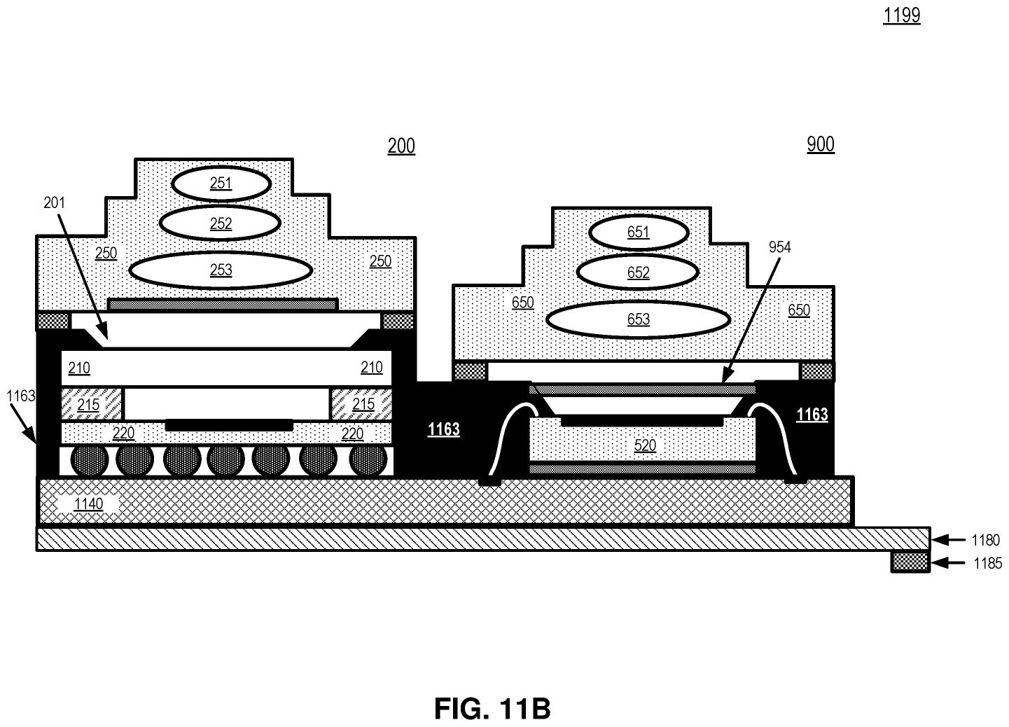

FIG. 11A illustrates an imaging module 1100 that includes a plurality of camera modules, in accordance with aspects of the disclosure. In FIG. 11A, camera module 200 and camera module 900 are electrically coupled to PCB layer 1140. Flex circuit layer 1180 is electrically coupled to PCB layer 1140 and connector 1185 is electrically coupled to flex circuit layer 1180. Image sensor 220 of camera module 200 and image sensor die 520 of camera module 900 may receive electrical power from connector 1185 via flex circuit layer 1180. Connector 1185 may deliver first image signals of first images captured by image sensor 220 of camera module 200. Connector 1185 may also deliver second image signals of second images captured by image sensor die 520 of camera module 900.

FIG. 11B illustrates an imaging module 1199, in accordance with aspects of the disclosure. Imaging module 1199 differs from imaging module 1100 in that molding compound 1163 is contiguous between camera modules 200 and 900. In an embodiment, a contiguous layer of molding compound 1163 shields ambient light from both image sensors 220 and image sensor die 520, in FIG. 11B.

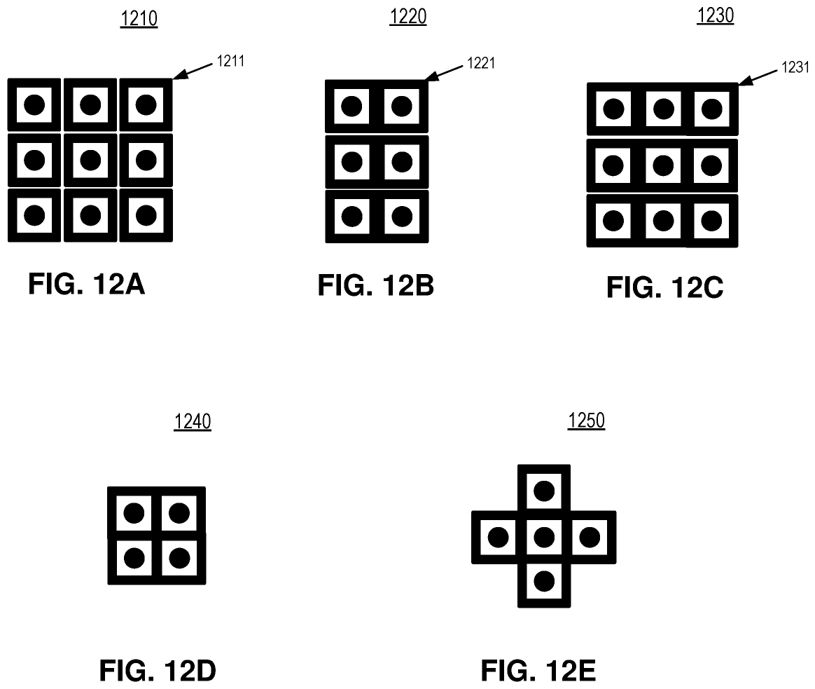

FIGS. 12A-12E illustrate imaging module array geometrical formats that include a plurality of camera modules, in accordance with aspects of the disclosure. FIGS. 12A-12E illustrate that various camera modules of this disclosure may be arranged in various geometric configurations.

FIG. 12A illustrates a 3×3 imaging module array 1210 including nine camera modules 1211. Each camera module 1211 may include camera module 200, for example.

FIG. 12B illustrates a 3×2 imaging module array 1220 including three camera modules 1221. Each camera module 1221 may include two camera modules 200, for example. In an embodiment, the molding compound 263 may be formed on the two camera modules 200 in a same fabrication process step so that the molding compound 263 forms a contiguous layer between the two camera modules 200. This may advantageously decrease the dimensions between the two camera modules 200 in camera module 1221.

FIG. 12C illustrates a 3×3 imaging module array 1230 including three camera modules 1231. Each camera module 1231 may include three camera modules 200, for example. In an embodiment, the molding compound 263 may be formed on the three camera modules 200 in a same fabrication process step so that the molding compound 263 forms a contiguous layer between the three camera modules 200 of camera module 1231. This may advantageously decrease the dimensions between the three camera modules 200 in camera module 1231.

FIG. 12D illustrates a 2×2 imaging module array 1240. Camera module 1240 may include four camera modules 200, for example. In an embodiment, the molding compound 263 may be formed on the four camera modules 200 in a same fabrication process step so that the molding compound 263 forms a contiguous layer between the four camera modules 200. This may advantageously decrease the dimensions between the four camera modules 200 in camera module 1240.

FIG. 12E illustrates an imaging module array 1250 arranged as an addition symbol (“+”). Camera module 1250 may include five camera modules 200, for example. In an embodiment, the molding compound 263 may be formed on the five camera modules 200 in a same fabrication process step so that the molding compound 263 forms a contiguous layer between the five camera modules 200 in camera module 1250. This may advantageously decrease the dimensions between the five camera modules 200 in camera module 1250.

FIGS. 12A-12E illustrate example geometric arrangements of camera modules and those skilled in the art appreciate that other geometric arrangements may also be used, in accordance with the devices in this disclosure. And, where more than one camera module is utilized in a camera module array, it may be advantageous to form the molding compound 263 of multiple camera module in the same fabrication process over camera modules sharing a same substrate (e.g. PCB layer 240) to reduce fabrication time and cost and reduce the dimensions between camera modules. Once the molding compound 263 is cured, the camera modules sharing the same substrate may then be cut into various geometric configurations.

Embodiments of the invention may include or be implemented in conjunction with an artificial reality system. Artificial reality is a form of reality that has been adjusted in some manner before presentation to a user, which may include, e.g., a virtual reality (VR), an augmented reality (AR), a mixed reality (MR), a hybrid reality, or some combination and/or derivatives thereof. Artificial reality content may include completely generated content or generated content combined with captured (e.g., real-world) content. The artificial reality content may include video, audio, haptic feedback, or some combination thereof, and any of which may be presented in a single channel or in multiple channels (such as stereo video that produces a three-dimensional effect to the viewer). Additionally, in some embodiments, artificial reality may also be associated with applications, products, accessories, services, or some combination thereof, that are used to, e.g., create content in an artificial reality and/or are otherwise used in (e.g., perform activities in) an artificial reality. The artificial reality system that provides the artificial reality content may be implemented on various platforms, including a head-mounted display (HMD) connected to a host computer system, a standalone HMD, a mobile device or computing system, or any other hardware platform capable of providing artificial reality content to one or more viewers.

The term “processing logic” in this disclosure may include one or more processors, microprocessors, multi-core processors, Application-specific integrated circuits (ASIC), and/or Field Programmable Gate Arrays (FPGAs) to execute operations disclosed herein. In some embodiments, memories (not illustrated) are integrated into the processing logic to store instructions to execute operations and/or store data. Processing logic may also include analog or digital circuitry to perform the operations in accordance with embodiments of the disclosure.

A “memory” or “memories” described in this disclosure may include one or more volatile or non-volatile memory architectures. The “memory” or “memories” may be removable and non-removable media implemented in any method or technology for storage of information such as computer-readable instructions, data structures, program modules, or other data. Example memory technologies may include RAM, ROM, EEPROM, flash memory, CD-ROM, digital versatile disks (DVD), high-definition multimedia/data storage disks, or other optical storage, magnetic cassettes, magnetic tape, magnetic disk storage or other magnetic storage devices, or any other non-transmission medium that can be used to store information for access by a computing device.

Communication channels may include or be routed through one or more wired or wireless communication utilizing IEEE 802.11 protocols, BlueTooth, SPI (Serial Peripheral Interface), I²C (Inter-Integrated Circuit), USB (Universal Serial Port), CAN (Controller Area Network), cellular data protocols (e.g. 3G, 4G, LTE, 5G), optical communication networks, Internet Service Providers (ISPs), a peer-to-peer network, a Local Area Network (LAN), a Wide Area Network (WAN), a public network (e.g. “the Internet”), a private network, a satellite network, or otherwise.

A computing device may include a desktop computer, a laptop computer, a tablet, a phablet, a smartphone, a feature phone, a server computer, or otherwise. A server computer may be located remotely in a data center or be stored locally.

The above description of illustrated embodiments of the invention, including what is described in the Abstract, is not intended to be exhaustive or to limit the invention to the precise forms disclosed. While specific embodiments of, and examples for, the invention are described herein for illustrative purposes, various modifications are possible within the scope of the invention, as those skilled in the relevant art will recognize.

These modifications can be made to the invention in light of the above detailed description. The terms used in the following claims should not be construed to limit the invention to the specific embodiments disclosed in the specification. Rather, the scope of the invention is to be determined entirely by the following claims, which are to be construed in accordance with established doctrines of claim interpretation.

What is claimed is:

1. A camera module comprising:
a chip scale package including an image sensor;
a lens assembly configured to focus image light to the image sensor; and
molding compound disposed around the chip scale package, wherein the molding compound shields ambient light from becoming incident onto the image sensor.

2. The camera module of claim 1, wherein the molding compound is a mounting surface that supports the lens assembly.

3. The camera module of claim 2, wherein the molding compound adheres the lens assembly to the chip scale package.

4. The camera module of claim 2, wherein an adhesive layer adheres the lens assembly to the molding compound.

5. The camera module of claim 1, wherein the molding compound is an epoxy molding compound (EMC) molded around the chip scale package.

6. The camera module of claim 1, wherein:
the chip scale package includes a coverglass layer disposed between the lens assembly and the image sensor, and
the molding compound surrounds sides of the coverglass layer and the image sensor.

7. The camera module of claim 6, wherein a portion of the molding compound is disposed between the coverglass layer and the lens assembly.

8. The camera module of claim 1 further comprising:
a printed circuit board (PCB), wherein the molding compound adheres the chip scale package to the PCB.

9. The camera module of claim 1, wherein the molding compound disposed around the chip scale package is substantially a same width as the lens assembly.

10. An imaging module comprising:
a chip scale package including a first image sensor;
a first lens assembly configured to focus image light to the first image sensor;
a second image sensor;
a second lens assembly configured to focus image light to the second image sensor; and
molding compound disposed around the first image sensor and disposed around the second image sensor, wherein the molding compound shields ambient light from becoming incident onto the first image sensor and the second image sensor.

11. The imaging module of claim 10 further comprising:
a printed circuit board (PCB), wherein:
the first image sensor is electrically coupled to the PCB, and
the second image sensor is electrically coupled to the PCB.

12. The imaging module of claim 11 further comprising:
a connector configured to:
deliver first image signals of first images captured by the first image sensor, and
deliver second image signals of second images captured by the second image sensor.

13. The imaging module of claim 10, wherein the molding compound is a plastic polymer molded around the first image sensor and the second image sensor.

14. The imaging module of claim 10, wherein the first image sensor is disposed adjacent to the second image sensor to share an almost same optical perspective as the second image sensor.

15. The imaging module of claim 10, wherein the second image sensor is included in a second chip scale package.

16. The imaging module of claim 10, wherein the molding compound supports the first lens assembly.

17. The imaging module of claim 16, wherein the molding compound adheres the first lens assembly to the chip scale package.

18. The imaging module of claim 16 further comprising:
an adhesive layer adhering the first lens assembly to the molding compound.

19. The imaging module of claim 10, wherein the molding compound disposed around the chip scale package is substantially a same width as the first lens assembly.

20. A camera module comprising:
a printed circuit board;
an image sensor;
a solder ball grid array electrically coupling the image sensor to the printed circuit board;
a lens assembly configured to focus image light to the image sensor; and
molding compound disposed around the image sensor to shield ambient light from becoming incident onto the image sensor while allowing the image light from the lens assembly to become incident onto the image sensor.
